(19) United States
(12) Patent Application Publication
(10) Pub. No.: US 2025/0285976 A1
(43) Pub. Date: Sep. 11, 2025

(54) POWER RAIL CAP FOR DEVICES WITH BACKSIDE METALLIZATION

(71) Applicant: International Business Machines Corporation, Armonk, NY (US)

(72) Inventors: Xiaoming Yang, Clifton Park, NY (US); Ruilong Xie, Niskayuna, NY (US); Ravikumar Ramachandran, Pleasantville, NY (US); Chen Zhang, Santa Clara, CA (US)

(21) Appl. No.: 18/599,896

(22) Filed: Mar. 8, 2024

(51) Int. Cl. H01L 23/528; H01L 23/522; H01L 29/06; H01L 29/423; H01L 29/66; H01L 29/775; H01L 29/786

(52) U.S. Cl. CPC H01L 23/5286; H01L 23/5226; H10D 30/014; H10D 30/43; H10D 30/6735; H10D 30/6757; H10D 62/121

(57) ABSTRACT

A semiconductor structure that includes the first portion of a source/drain (S/D) contact connecting to the first portion of the power rail, where the first portion of the S/D contact has a width that is equal to the width of the top surface of the first portion of the power rail. The width of the contact area of the first portion of the S/D contact with the first portion of power rail is greater than the width of the contact area of conventionally formed S/D contact with the power rail. The first portion of the power rail is adjacent to at least one semiconductor device. A power rail cap is one the second portion of a power rail. The power rail which can be a buried power rail connects by one or more backside vias to a backside metal layer.

### BACKGROUND

The disclosure generally relates to forming a semiconductor device and more particularly, to advanced semiconductor devices with power rails and backside power delivery networks.

The amount of data we process is rapidly increasing at a rate higher than that of Moore's law. Increasing system performance requirements, driven at least in part by the increasing use of artificial intelligence, continue to drive tighter pitches in semiconductor devices and smaller semiconductor chips. For logic device and memory device scaling at the two-nanometer node, planar and non-planar semiconductor device structures, such as metal-oxide-semiconductor field-effect transistors (MOSFETs), must be scaled to smaller dimensions.

As the semiconductor industry continues to drive to the two-nanometer technology node with tighter pitches and smaller device elements with increasing performance, increased use of backside interconnect layers for a backside power delivery network is emerging. Creating backside interconnect layers below the front-end-of-line semiconductor devices provides improved power performance and more routing options for semiconductor devices relieving some of the BEOL wiring congestion. A backside power delivery network improves semiconductor device gate delay and reduces BEOL wiring congestion.

In leading-edge semiconductor technologies, effective power delivery while reducing device cell sizes is problematic as typical power and ground rails are wider than routing lines. Power rails buried in portions of the semiconductor substrate connecting to the backside power delivery networks reduce the area lost at cell boundaries for power and ground delivery and enable smaller device cell size.

### SUMMARY

The following presents a summary to provide a basic understanding of one or more embodiments of the disclosure. This summary is not intended to identify key elements or delineate any scope of the particular embodiments or any scope of the claims.

Aspects of the disclosed invention relate to a semiconductor structure that includes the first portion of a source/drain (S/D) contact connecting to the first portion of the power rail, where the first portion of the S/D contact has a width that is equal to the width of the top surface of the first portion of the power rail. The first portion of the power rail is adjacent to at least one semiconductor device. A power rail cap is on the second portion of a power rail. The power rail connects by one or more backside vias to a backside metal layer.

Aspects of the disclosed invention relate to a semiconductor structure that includes a power rail between two gate-all-around field-effect transistors (GAA FETs), where the power rail with a liner is in a portion of the semiconductor substrate. The semiconductor structure includes the first portion of a source/drain (S/D) contact connecting to the first portion of the power rail, where the width of the first portion of the S/D contact is equal to the width of the top surface of the first portion of the power rail. The power rail connects by one or more backside vias to a backside metal layer of one or more backside wiring layers. The semiconductor structure includes a power rail cap contacting the top surface of the second portion of the power rail.

Aspects of the disclosed invention relate to a method of forming the top surface of the first portion of a power rail between two semiconductor devices contacting a portion of a drain contact and the second portion of the top surface of the power rail covered by a power rail cap. The method includes forming two semiconductor devices, such as but not limited to two nanosheet gate-all-around field-effect transistors with the power rail between the two semiconductor devices. The method includes recessing the top surface of the power rail below the top surface of a first dielectric material. The method includes depositing a power rail cap material over the recessed power rail and the first dielectric material. The method includes performing a chemical-mechanical polish to remove the power rail cap above the surface of the first dielectric material. The method includes depositing a second dielectric material over the first dielectric material and removing portions of the first dielectric material and the second dielectric material over the source/drains of the two semiconductor devices. The method includes creating an opening over each source/drain of the two semiconductor devices by removing portions of the first dielectric material and the second dielectric material, The method includes removing a portion of the power rail cap above a first portion of the power rail, wherein the portion of the power rail cap removed contacts an opening over the top surface of power rail adjacent to one of the source/drains of one of the two semiconductor devices. The method includes depositing a contact metal, wherein the contact metal deposits on the second dielectric material, on the top surface of the source/drains, and on the top surface of the first portion of the power rail that is not covered by the power rail cap. The contact metal on the power rail replaces the removed portion of the power rail cap. Furthermore, the method includes removing the contact metal above the second dielectric material, wherein a first portion of the contact metal resides on a portion of the top surface of the power rail and a second portion of the contact metal resides on each of the source/drains.

### BRIEF DESCRIPTION OF THE DRAWINGS

The above and other aspects, features, and advantages of various embodiments of the present invention will be more apparent from the following description taken in conjunction with the accompanying drawings.

FIG. 1 depicts a top view of an illustration of a semiconductor design of an advanced semiconductor device, in accordance with an embodiment of the present invention.

FIG. 2A depicts a cross-sectional view Y1-Y1 of a semiconductor structure after performing a chemical-mechanical polish (CMP) to remove excess power rail metal of a backside power rail, in accordance with an embodiment of the present invention.

FIG. 2B depicts a cross-sectional view Y2-Y2 of the semiconductor structure after performing a chemical-mechanical polish (CMP) to remove excess power rail metal of a backside power rail, in accordance with an embodiment of the present invention.

FIG. 3A depicts a cross-sectional view Y1-Y1 of the semiconductor structure after recessing the backside power rail, in accordance with an embodiment of the present invention.

FIG. 3B depicts a cross-sectional view Y2-Y2 of the semiconductor structure after recessing the backside power rail, in accordance with an embodiment of the present invention.

FIG. 4A depicts a cross-sectional view Y1-Y1 of the semiconductor structure after depositing a power rail cap material, in accordance with an embodiment of the present invention.

FIG. 4B depicts a cross-sectional view Y2-Y2 of the semiconductor structure after depositing a power rail cap material, in accordance with an embodiment of the present invention.

FIG. 5A depicts a cross-sectional view Y1-Y1 of the semiconductor structure after performing a CMP to remove excess power rail cap material, in accordance with an embodiment of the present invention.

FIG. 5B depicts a cross-sectional view Y2-Y2 of the semiconductor structure after performing a CMP to remove excess power rail cap material, in accordance with an embodiment of the present invention.

FIG. 6A depicts a cross-sectional view Y1-Y1 of the semiconductor structure after depositing an interlayer dielectric (ILD) material, in accordance with an embodiment of the present invention.

FIG. 6B depicts a cross-sectional view Y2-Y2 of the semiconductor structure after depositing the ILD material, in accordance with an embodiment of the present invention.

FIG. 7A depicts a cross-sectional view Y1-Y1 of the semiconductor structure after depositing and patterning a layer of anti-reflective coating (ARC) and organic planarization layer (OPL), in accordance with an embodiment of the present invention.

FIG. 7B depicts a cross-sectional view Y2-Y2 of the semiconductor structure after depositing and patterning a layer of ARC and OPL, in accordance with an embodiment of the present invention.

FIG. 8A depicts a cross-sectional view Y1-Y1 of the semiconductor structure after etching source/drain (S/D) contact via holes in the Y2-Y2 cross-sectional view, in accordance with an embodiment of the present invention.

FIG. 8B depicts a cross-sectional view Y2-Y2 of the semiconductor structure after etching S/D contact via holes, in accordance with an embodiment of the present invention.

FIG. 9A depicts a cross-sectional view Y1-Y1 of the semiconductor structure after removing the exposed power rail cap material in cross-sectional view Y2-Y2, in accordance with an embodiment of the present invention.

FIG. 9B depicts a cross-sectional view Y2-Y2 of the semiconductor structure after removing the exposed power rail cap material, in accordance with an embodiment of the present invention.

FIG. 10A depicts a cross-sectional view Y1-Y1 of the semiconductor structure after removing the OPL and depositing a contact metal, in accordance with an embodiment of the present invention.

FIG. 10B depicts a cross-sectional view Y2-Y2 of the semiconductor structure after removing the OPL and depositing the contact metal, in accordance with an embodiment of the present invention.

FIG. 11 depicts a top view of an illustration of a semiconductor design of the advanced semiconductor device with a power rail cap and source/drain contacts, in accordance with an embodiment of the present invention.

FIG. 12A depicts a cross-sectional view Y1-Y1 of the semiconductor structure after a CMP removes the excess S/D contact metal, in accordance with an embodiment of the present invention.

FIG. 12B depicts a cross-sectional view Y2-Y2 of the semiconductor structure after the CMP removes the excess S/D contact metal, in accordance with an embodiment of the present invention.

FIG. 13A depicts a cross-sectional view Y1-Y1 of the semiconductor structure after forming a backside power delivery network (BSPDN), in accordance with an embodiment of the present invention.

FIG. 13B depicts a cross-sectional view Y2-Y2 of the semiconductor structure after forming BSPDN, in accordance with an embodiment of the present invention.

### DETAILED DESCRIPTION

Embodiments of the present invention recognize that the overlap or contact area between a source/drain contact and backside power rail is small in conventionally formed advanced semiconductor devices such as nanosheet gate-all-around field-effect transistors (GAA FETs). The contact area of the source/drain contact with the power rail creates a high electrical resistance of the power rail and source/drain contact. A semiconductor structure that provides a larger contact area between the power rail and the source/drain contacts would be desirable, especially in advanced semiconductor devices using the power rail to connect to a backside power delivery network.

Additionally, embodiments of the present invention recognize that over-etching of the source/drain contact opening can damage the surface of the power rail metal. For example, over-etching of the source/drain contact opening by reactive ion etch (RIE) can damage the surface of the power rail metal and increase the electrical resistance of the top portion of the power rail metal.

Aspects of the present invention provide a semiconductor structure that includes the first portion of a source/drain (S/D) contact connecting to the first portion of the power rail, wherein the first portion of the S/D contact contacts the top surface of the first portion of the power rail. The horizontal width of the contact area of the first portion of the source/drain contact connecting to the second portion of the power rail is equal to the width of the top surface of the power rail (e.g., the width of the top surface of the first portion of the power rail). The first portion of the power rail is adjacent to at least one source/drain of at least one adjacent semiconductor device.

The semiconductor structure includes a power rail cap on the second portion of the power rail. The second portion of the power rail is adjacent to at least one gate of at least one adjacent semiconductor device. The power rail includes a liner electrically isolating the sidewall of the power rail from one or more gate structures of the adjacent semiconductor devices and, in some cases, from one or more sidewalls of the source/drains of the adjacent semiconductor devices.

In various aspects, the power rail can be a buried power rail residing in a shallow trench isolation (STI) in a portion of the semiconductor substrate that extends up between the adjacent semiconductor devices and into a layer of interlayer dielectric (ILD). The top surface of the power rail is above the gate structures and source/drains of one or more adjacent semiconductor devices. The power rail connects by one or more backside vias to a first backside metal layer that can be in a backside power delivery network.

The first portion of the first S/D contact connecting to the first portion of the power rail is above the top surface of the first source/drain of at least one of one or more adjacent semiconductor devices. The first portion of the first S/D contact connecting to the first portion of the power rail has a height that is equal to the thickness of the power rail cap directly on the second portion of the power rail. A second portion of the first S/D contact connects to the top surface of one of the first source/drain.

The second S/D contact connecting the top surface of the second source/drain of at least one of the one or more adjacent semiconductor devices extends upward through one or more layers of ILD to a via. The via connects to at least one metal layer and the frontside interconnect wiring.

The power rail includes a liner contacting and surrounding a sidewall of the power rail. In various embodiments, the liner electrically isolates the power rail from the gate structures of the adjacent semiconductor devices. In an embodiment, the liner electrically isolates the power rail from the semiconductor substrate when the power rail is not in an STI in the semiconductor substrate or when the power rail extends below the bottom surface of the STI. The power rail, which may be called a buried power rail, connects by a backside via to the first metal layer of a power delivery network.

The semiconductor device can be an advanced semiconductor device such as a GAA FET. The semiconductor device is not limited to a GAA FET but can be another type of logic device (e.g., a complementary metal-oxide semiconductor (CMOS) device, a planar FET, stacked GAA FETs, a complementary FET (CFET), a finFET), or a memory device included a stacked memory device.

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. Some of the process steps, depicted, can be combined as an integrated process step. In addition, descriptions of well-known functions and constructions may be omitted for clarity and conciseness.

The terms and words used in the following description and claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is to be understood that the singular forms “a,” “an,” and “the” include plural referents unless the context dictates otherwise. Thus, for example, reference to “a component surface” includes reference to one or more of such surfaces unless the context dictates otherwise.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “on”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” or “contact” means that a first element, such as a first structure, and a second element, such as a second structure, are connected without any intermediary conducting, insulating, or semiconductor layers at the interface of the two elements.

In the interest of not obscuring the presentation of embodiments of the present invention, in the following detailed description, some processing steps or operations that are known in the art may have been combined for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Detailed embodiments of the claimed structures and methods are disclosed herein. The method steps described below do not form a complete process flow for manufacturing integrated circuits on semiconductor chips. The present embodiments can be practiced in conjunction with the integrated circuit fabrication techniques for semiconductor chips and devices currently used in the art, and only so much of the commonly practiced process steps are included as are necessary for an understanding of the described embodiments. The figures represent cross-section portions of a semiconductor chip or a substrate, such as a semiconductor wafer during fabrication, and are not drawn to scale, but instead are drawn to illustrate the features of the described embodiments. Specific structural and functional details disclosed herein are not to be interpreted as limiting, but merely as a representative basis for teaching one skilled in the art to variously employ the methods and structures of the present disclosure. In the description, details of well-known features and techniques may be omitted to avoid unnecessarily obscuring the presented embodiments.

References in the specification to “one embodiment”, “other embodiment”, “another embodiment”, “an embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to affect such feature, structure, or characteristic in connection with other embodiments whether or not explicitly described.

Reference will now be made in detail to the embodiments of the present invention, examples of which are illustrated in the accompanying drawings, wherein like reference numerals refer to like elements throughout.

Deposition processes for materials, such as metal materials, dielectric materials, and sacrificial materials include but are not limited to chemical vapor deposition (CVD), physical vapor deposition (PVD), atomic layer deposition (ALD), molecular layer deposition (MLD), high-density plasma (HDP) deposition, or gas cluster ion beam (GCIB) deposition. Variations of CVD processes include but are not limited to, atmospheric pressure CVD (APCVD), low-pressure CVD (LPCVD), plasma enhanced CVD (PECVD), and metal-organic CVD (MOCVD), and combinations thereof may also be employed.

Removal, removing, or etching as used herein includes but is not limited to patterning using one of lithography, photolithography, an extreme ultraviolet (EUV) lithography process, or any other known semiconductor patterning process followed by one or more etching processes. Some examples of etching processes include but are not limited to the following processes, such as a dry etching process using a reactive ion etch (RIE) or ion beam etch (IBE), a wet chemical etch process, or a combination of these etching processes.

Reference is now made to the figures. The figures provide schematic cross-sectional illustrations of semiconductor devices at intermediate stages of fabrication, according to one or more embodiments of the invention. The device provides schematic representations of the devices of the invention and is not to be considered accurate or limiting with regard to the device element scale.

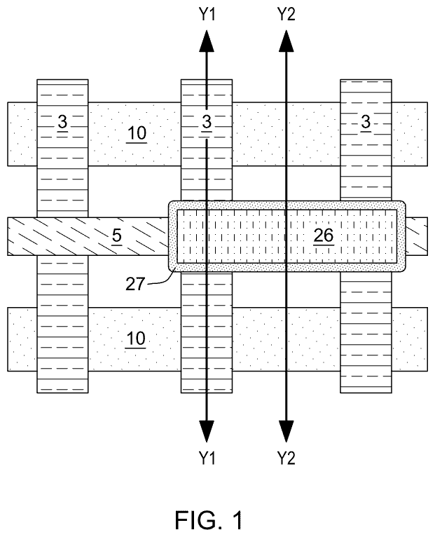

FIG. 1 depicts a top view of an illustration of semiconductor design of an advanced semiconductor device, in accordance with an embodiment of the present invention. As depicted, FIG. 1 includes active region 10, gate structures 3, gate trench 5, and power rail 26 with liner 27 where FIG. 1 depicts one example of two advanced semiconductor devices where the example depicts two nanosheet field-effect transistors (FETs) with power rail 26 formed on semiconductor substrate 2 covered by etch stop layer 11 and semiconductor material 4

FIG. 1 also illustrates the location of cross-sectional views Y1-Y1 through one of gate structures 3 and the location of cross-sectional views Y2-Y2 that are parallel to and between two adjacent gate structures 3. As depicted, cross-sectional views Y2-Y2 cut through at least a portion of power rail 26 with liners 27, and cross-sectional views Y1-Y1 run along and through one of gate structures 3 and, cut through different portions of power rail 26 and liner 27. Cross-sectional views Y1-Y1 are illustrated in the FIGs. identified with the letter “A”. Cross-sectional views Y2-Y2 are illustrated in the FIGs. identified with the letter “B” (e.g., 1B, 2B, 3B, 4B, 5B, 6B, 7B, 8B. 9B. 10B, 12B, 13B, and 14B).

While FIG. 1 depicts one example of a semiconductor device design that can use a power rail cap, in other examples, more than two semiconductor devices can be depicted where each of the semiconductor devices can be a logic semiconductor device, a memory device, a stacked logic device, a stacked memory device, or any other type of semiconductor device using a power rail connecting to a backside power delivery network (BSPDN) can be used with the processes discussed later in embodiments of the present invention using for forming a power rail cap and a larger S/D contact area with power rail 26.

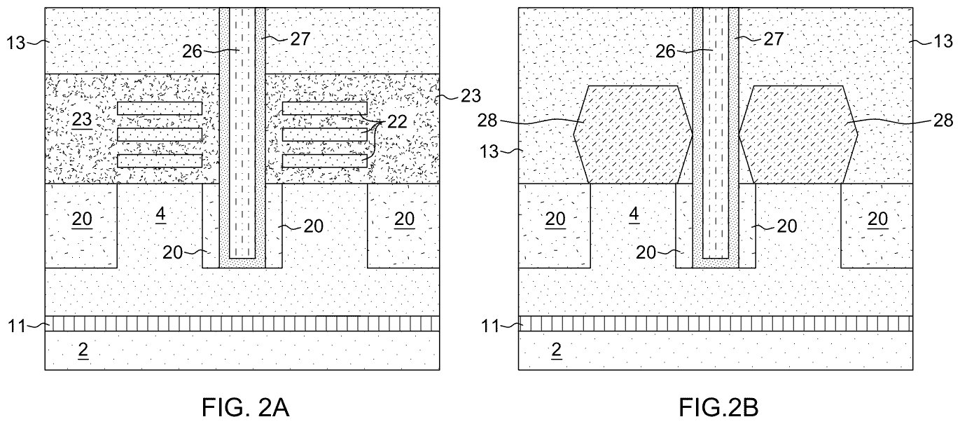

FIG. 2A depicts a cross-sectional view Y1-Y1 of a semiconductor structure after performing a CMP to remove excess power rail metal of power rail 26, in accordance with an embodiment of the present invention. FIG. 2A includes substrate 2, etch stop layer 11, semiconductor material 4, shallow trench isolation (STI) 20, channels 22, gate 23, ILD 13, power rail 26 which is a backside power rail, and liner 27.

As depicted, FIG. 2A depicts cross-sectional view Y1-Y1 of two adjacent nanosheet gate-all-around field-effect transistors (GAA FETs) separated by power rail 26. As known to one skilled in the art, each of the GAA FETs in cross-sectional view Y1-Y1 depicted in FIG. 2A includes at least channels 22 which can be composed of portions of silicon nanosheets, and gate 23 which may include a gate dielectric, a gate electrode, and a work function metal. In other examples, the cross-sectional view Y1-Y1 after forming power rail 26 can depict one or more of another type of logic device (e.g., stacked logic devices) adjacent to power rail 26 or one or more memory devices including stacked memory devices adjacent to power rail 26. As depicted in FIG. 2A, gate 23 contacts portions of liner 27 on power rail 26. In other examples, gate 23 can be adjacent to but not contacting liner 27.

In FIG. 2A, the top surface of power rail 26 with liner 27 in a portion of ILD 13 that is above and contacting gates 23. The bottom surface of power rail 26 with liner 27 is level with the bottom surface of the middle STI 20 residing in substrate 2. As known to one skilled in the art, power rail 26 can be a buried power rail. In other embodiments, power rail 26 with liner 27 extends below the bottom surface of STI 20. In an embodiment, power rail 26 with liner 27 is not in one of STI 20 but instead extends into a portion of substrate 2. In this embodiment, liner 27 electrical isolates power rail 26 from substrate 2.

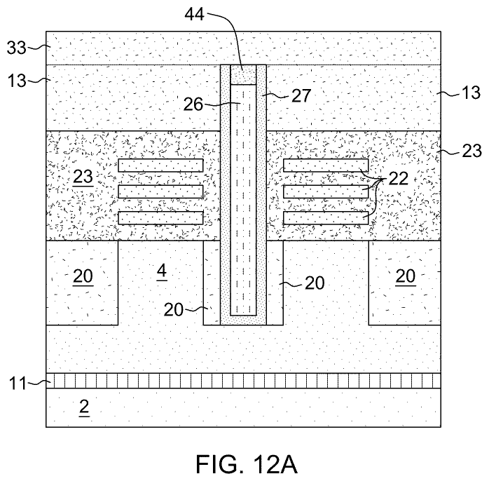

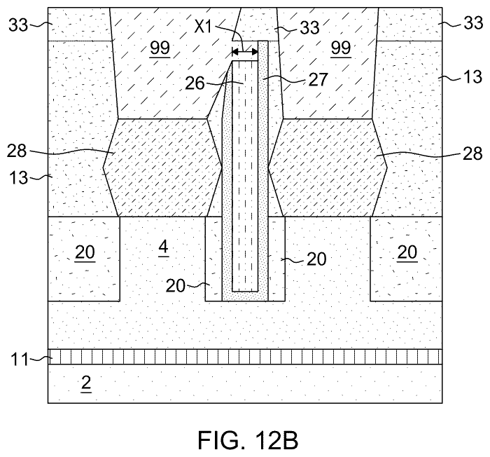

While FIG. 2A depicts a cross-sectional view Y1-Y1 of two GAA FETs, other embodiments of the present invention can include one or more GAA FETs, stacked FETs, complimentary FETS, planar FETs, memory devices, stacked memory devices, CMOS devices, passive devices, and other logic devices. As depicted later in FIG. 12B, the increased power rail and S/D contact area has an increased contact area width, depicted as X1 in FIG. 12B can also be created in other semiconductor devices with a power rail connecting to an S/D contact and to a backside metal layer (e.g., the first metal layer of a BSPDN). The present invention and methods of a semiconductor structure with a power rail or a buried power rail that has an increased width of the contact area between a power rail and one or more adjacent S/D contacts is not limited to the two GAA FETs depicted in FIGS. 2A and 2B but can be applied to other semiconductor devices as previously discussed.

The semiconductor structure of the portion of the two GAA FETs depicted in FIG. 2A can be formed using known nanosheet semiconductor processes for fabricating GAA FETs and known semiconductor processes for power rail fabrication.

As depicted in FIG. 2A and in FIG. 2B, the top surface of power rail 26 is above each of gates 23 and S/D 28. The top surface of power rail 26 is level with the top surface of ILD 13. The bottom surface of liner 27 on power rail 26 is level with the bottom surface of one of STI 20 that is in a portion of semiconductor material 4. In various embodiments, semiconductor material 4 is considered a portion of the semiconductor substrate. As depicted, the sidewall of power rail 26 is electrically isolated from the two adjacent gates 23 by liner 27. In some cases, another dielectric material may be between liner 27 and gates 23.

FIG. 2B depicts a cross-sectional view Y2-Y2 of the semiconductor structure after performing the CMP to remove excess power rail metal of power rail 26, in accordance with an embodiment of the present invention. As depicted, FIG. 2B includes substrate 2, etch stop layer 11, semiconductor material 4, STI 20, channels 22, gate 23, ILD 13, power rail 26, and liner 27.

FIG. 2B depicts the cross-sectional view Y2-Y2 of the two adjacent GAA FETs separated by power rail 26. As depicted in FIG. 2B, a portion of each of S/D 28 contact liner 27 however, in other examples, one of S/D 28 contacts liner 27, or in yet other examples, S/D 28 may be adjacent to but not contacting S/D 28 (e.g., a portion of another dielectric material or ILD 13 may be between S/D 28 and liner 27).

As previously discussed, in other examples, the cross-sectional view Y2-Y2 after forming power rail 26 can depict one or more of another type of logic device (e.g., stacked logic devices) adjacent to power rail 26 or one or more of a type of memory devices including stacked memory devices. As discussed above with respect to FIG. 2A, the semiconductor structure depicted in FIG. 2B can be formed using known semiconductor device fabrication processes for nanosheet GAA FETs and buried power rails. In FIG. 2B, power rail 26 with liner 27 is between two of S/D 28 and has a top surface that is above the top surface of each of S/D 28.

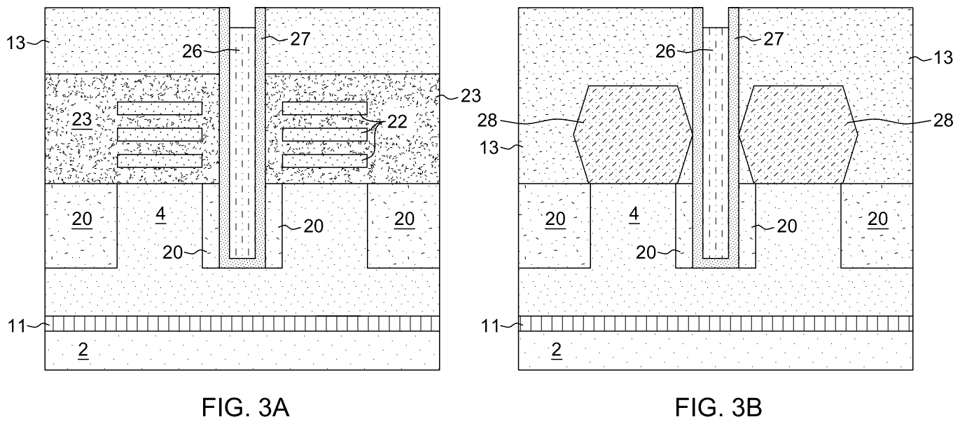

FIG. 3A depicts a cross-sectional view Y1-Y1 of the semiconductor structure after recessing power rail 26, in accordance with an embodiment of the present invention. As depicted, FIG. 3A includes the elements of FIG. 2A without the top portion of power rail 26.

Using known wet or dry etching processes for a power rail metal (e.g., copper), the top portion of power rail 26 can be removed. For example, using a known dry or wet metal etching process, at least 5 nm of the top portion of power rail 26 may be removed but the recessing of power rail 26 is not limited to removing this range (e.g., maybe 10 nm or more of the top surface of the power rail may be removed). As depicted, liner 27 can remain where the recessed portion of power rail 26 was.

FIG. 3B depicts a cross-sectional view Y2-Y2 of the semiconductor structure after recessing power rail 26, in accordance with an embodiment of the present invention. As depicted, FIG. 3B includes the elements of FIG. 2B without the top portion of power rail 26. As discussed above, at least 5 nm of power rail 26 and typically, 10 nm or more of power rail 26 may be removed leaving an exposed portion of liner 27 on ILD 13.

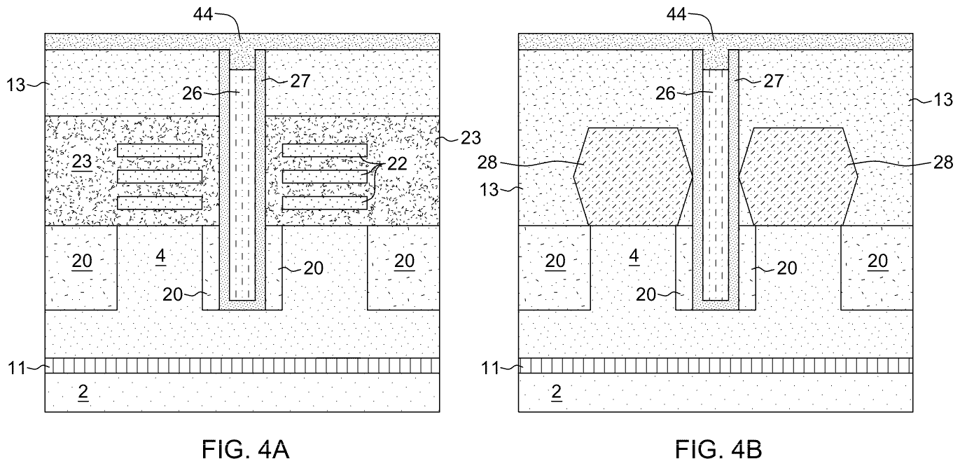

FIG. 4A depicts a cross-sectional view Y1-Y1 of the semiconductor structure after depositing a material for power rail cap 44, in accordance with an embodiment of the present invention. As depicted, FIG. 4A includes the elements of FIG. 3A and the material for power rail cap 44.

As depicted, the material for power rail cap 44 can be deposited over the exposed surfaces of ILD 13, liner 27, and power rail 26. The material for power rail cap 44 may be deposited by any semiconductor deposition process such as but not limited to atomic layer deposition (ALD), chemical vapor deposition (CVD), or plasma vapor deposition (PVD) with a depth sufficient to fill the recessed region of power rail 26 and to cover a top surface of ILD 13 (e.g., with at least 10 nm-50 nm or more of material for power rail cap 44).

The material for power rail cap 44 has a different etch rate than the material of ILD 13, liner 27, and power rail 26. For example, the material for power rail cap 44 can be silicon (Si), or silicon germanium (SiGe). In other examples, the material for power rail cap 44 may be another semiconductor or dielectric material with a different etch rate than ILD 13, liner 27, or power rail 26.

FIG. 4B depicts a cross-sectional view Y2-Y2 of the semiconductor structure after depositing a material for power rail cap 44, in accordance with an embodiment of the present invention. Cross-sectional view Y2-Y2 depicts the elements of FIG. 3B with the material for power rail cap 44 deposited as discussed above with reference to FIG. 4A on ILD 13, liner 27, and power rail 26.

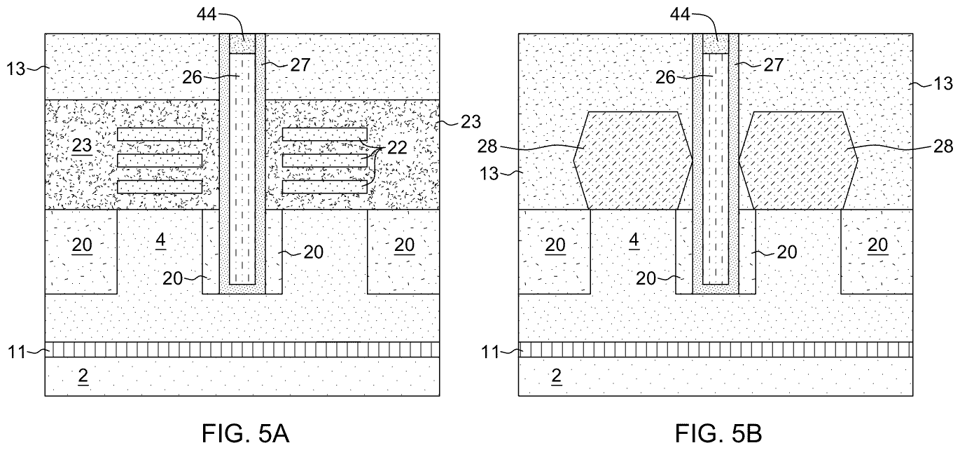

FIG. 5A depicts a cross-sectional view Y1-Y1 of the semiconductor structure after performing a CMP to remove the excess material for power rail cap 44, in accordance with an embodiment of the present invention. The CMP removes the material for power rail cap 44 from the top surface of ILD 13, as depicted in FIG. 5A. In other examples, a wet or dry etch process such as reactive ion etch (RIE) may remove portions of the material for power rail cap 44 from the top surface of ILD 13.

FIG. 5B depicts a cross-sectional view Y2-Y2 of the semiconductor structure after performing the CMP to remove the excess material for power rail cap 44, in accordance with an embodiment of the present invention. As depicted, FIG. 5B includes the elements of FIG. 4B without the top portion of power rail cap 44. The CMP or an etch process removes the excess metal material of power rail cap 44 from the top surface of ILD 13 to form power rail cap 44.

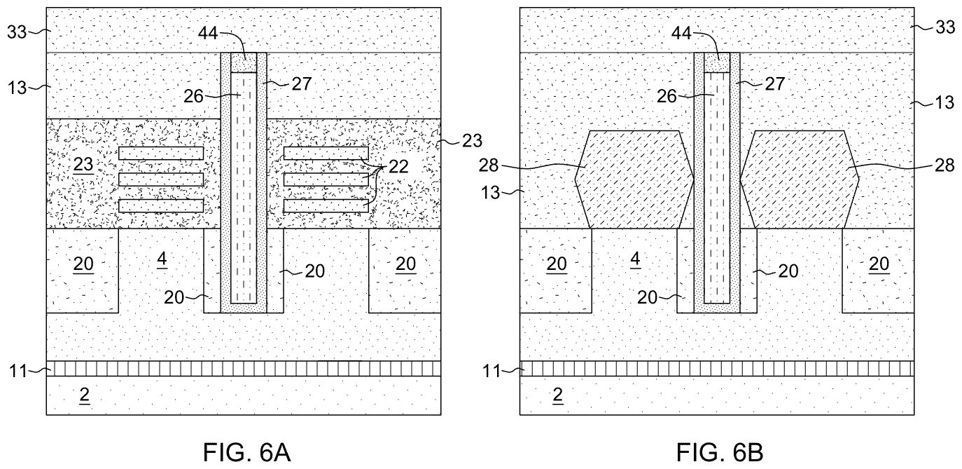

FIG. 6A depicts a cross-sectional view Y1-Y1 of the semiconductor structure after depositing ILD 33, in accordance with an embodiment of the present invention. As depicted, FIG. 6A includes the elements of FIG. 5A with ILD 33 deposited over the top surface of the semiconductor structure. ILD 33 can be deposited over exposed surfaces of ILD 13, liner 27, and power rail cap 44 using known ILD deposition processes (e.g., PVD).

FIG. 6B depicts a cross-sectional view Y2-Y2 of the semiconductor structure after depositing ILD 33, in accordance with an embodiment of the present invention. As depicted, FIG. 6A includes the elements of FIG. 5A with ILD 33 deposited over the exposed top surfaces of ILD 13, liner 27, and power rail cap 44.

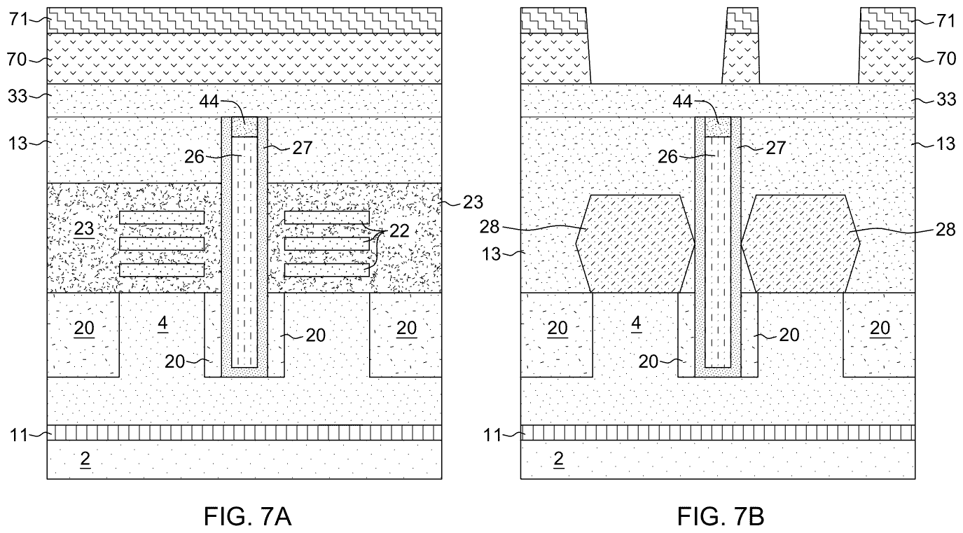

FIG. 7A depicts a cross-sectional view Y1-Y1 of the semiconductor structure after depositing and patterning a layer of ARC 71 and OPL 70, in accordance with an embodiment of the present invention. As depicted, FIG. 7A includes the elements of FIG. 6A with the layer of ARC 71 and OPL 70 on the top surface of ILD 33.

FIG. 7B depicts a cross-sectional view Y2-Y2 of the semiconductor structure after depositing and patterning the layer of ARC 71 and OPL 70, in accordance with an embodiment of the present invention. As depicted, FIG. 7A includes the elements of FIG. 6A with a portion of the layer of ARC 71 and OPL 70 on the top surface of ILD 33 after patterning ARC 71 and OPL 70. The deposition and patterning of ARC 71 and OPL 70 occurs using known deposition and lithographic processes. As depicted in FIG. 7B, portions of ARC 71 and OPL 70 are patterned and removed above each of S/D 28.

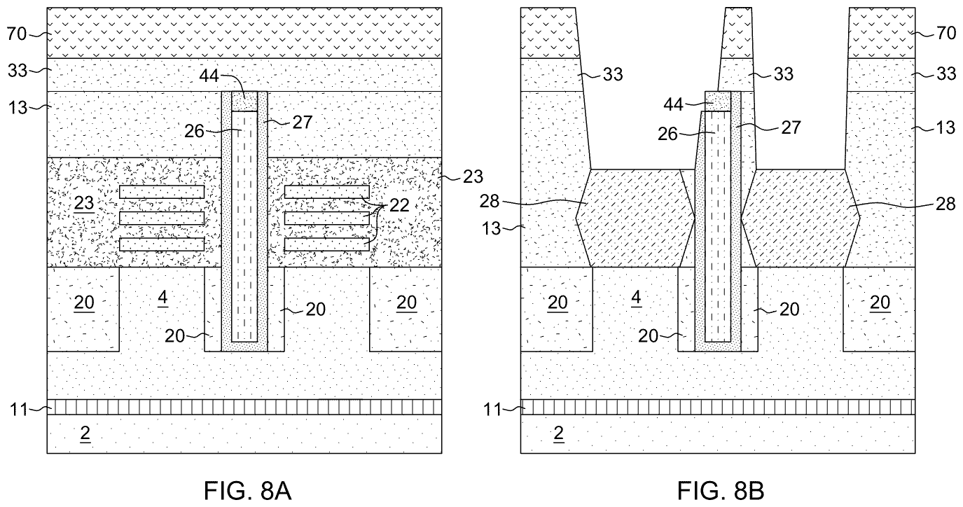

FIG. 8A depicts a cross-sectional view Y1-Y1 of the semiconductor structure after etching S/D contact via holes and removing ARC 71 in the Y2-Y2 cross-sectional view, in accordance with an embodiment of the present invention. As depicted, FIG. 8A includes the elements of FIG. 7A without ARC 71. Using known removal processes for anti-reflective materials, the layer of ARC 71 is removed in cross-sectional view Y1-Y1.

FIG. 8B depicts a cross-sectional view Y2-Y2 of the semiconductor structure after etching S/D contact via holes in ILD 33 and removing ARC 71, in accordance with an embodiment of the present invention. As depicted, FIG. 8B includes the elements of FIG. 7B without ARC 71 and without exposed portions of ILD 33, ILD 13 under the exposed portions of ILD 33, and a portion of liner 27. The exposed portions of ILD 33 are basically over each of S/D 28.

For example, using one or more of RIE and/or ion beam etch (IBE) can be performed to form two holes or openings in ILD 33 and ILD 13 for S/D contacts. As depicted in FIG. 8A, the leftmost S/D contact hole can have slightly angled sidewalls. The RIE or IBE etching process can be slightly angled to remove portions of ILD 33, ILD 13, a portion of liner 27, and in some cases, a portion of power rail cap 44 adjacent to and above the leftmost S/D 28. As depicted, at least a portion of power rail cap 44 adjacent to the S/D contact hole remains above the leftmost power rail 26. After the etching process, the top portion of liner 27 adjacent to the leftmost S/D 28 is removed in a portion of the RIE etched hole. The removed portion of liner 27 can be below the left side of the remaining portion of power rail cap 44. As depicted, liner 27 adjacent to S/D 28 has a lower top surface than the right-side portion of liner 27 below a portion of gate 23 and adjacent to right-side S/D 28.

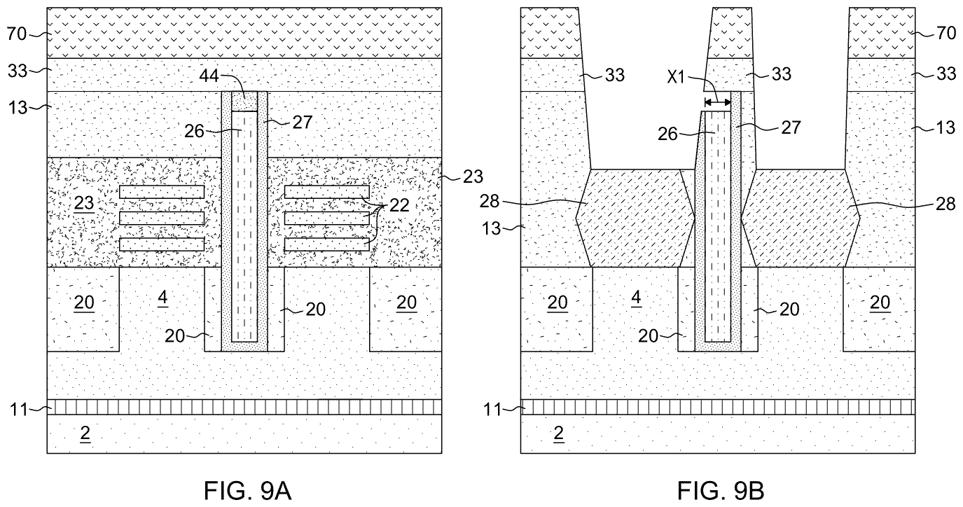

FIG. 9A depicts a cross-sectional view Y1-Y1 of the semiconductor structure after removing the exposed power rail cap material in cross-sectional view Y2-Y2, in accordance with an embodiment of the present invention. As depicted, FIG. 9A includes the elements of FIG. 8A. FIG. 9A is essentially the same as FIG. 8A. As depicted, FIG. 9A includes a portion of power rail cap 44 directly above and on power rail 26.

FIG. 9B depicts a cross-sectional view Y2-Y2 of the semiconductor structure after removing the exposed power rail cap 44, in accordance with an embodiment of the present invention. As depicted, FIG. 9B includes the elements of FIG. 8B without power rail cap 44. Also, illustrated in FIG. 9B is the width X1 of the exposed top surface of power rail 26. The exposed top surface of power rail 26 will contact a portion of the source/drain as depicted later in FIG. 12B.

For example, a wet etch can selectively remove power rail cap 44 above power rail 26. The opening over the leftmost S/D 28 has a notch in the sidewall that extends to the right above power rail 26. The notch, above a portion of power rail 26, has a bottom width that is the same as the width of power rail 26. The opening over the rightmost S/D 28 has a smooth, slightly angled sidewall. As depicted in FIG. 9B, width X1 is equal to the width of the exposed top surface of power rail 26.

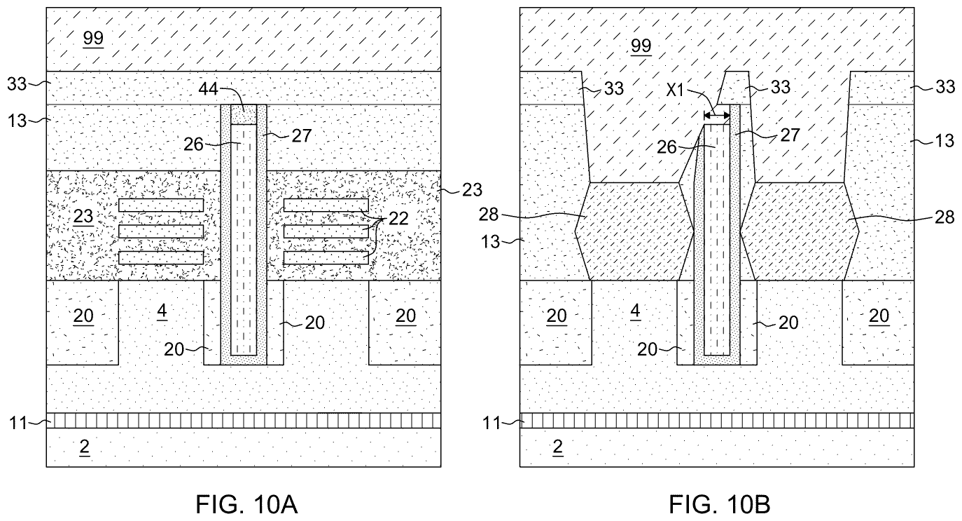

FIG. 10A depicts a cross-sectional view Y1-Y1 of the semiconductor structure after removing OPL 70 and depositing contact metal 99, in accordance with an embodiment of the present invention. As depicted, FIG. 10A includes the elements of FIG. 9A without OPL 70.

Using known processes (e.g., plasma ash processes and/or etching), OPL 70 can be removed. Contact metal 99 is not depicted in FIG. 10A.

FIG. 10B depicts a cross-sectional view Y2-Y2 of the semiconductor structure after removing OPL 70 and depositing contact metal 99, in accordance with an embodiment of the present invention. As depicted, FIG. 10B includes the elements of FIG. 9A without OPL 70 and with contact metal 99. Also, depicted in FIG. 10B is the width X1 of the notch depicted previously in FIG. 9B where X1 in FIG. 10B is now the width X1 of the contact area of contact metal 99 for the S/D contact of the leftmost S/D 28 with power rail 26. As depicted in FIG. 10B, X1 is the horizontal width of the top surface of power rail 26.

Using known methods (e.g., plasma ash and/or etching processes), OPL 70 can be removed. A liner (not depicted) can be conformally deposited directly on the exposed surfaces of the semiconductor structure (e.g., on ILD 33, on S/D 28, liner 27, and power rail 26 before contact material 99 deposition. In various embodiments, a conformal deposition of contact metal 99 occurs. The conformal deposition of contact metal 99 can fill the notch above power rail 26 and covers an exposed top surface of power rail 26. In some embodiments, a second deposition of contact metal 99 occurs, for example, by CVD, PVD, or electroplating. Contact metal 99 can be any contact metal. For example, contact metal 99 can be one of tungsten, cobalt, or ruthenium.

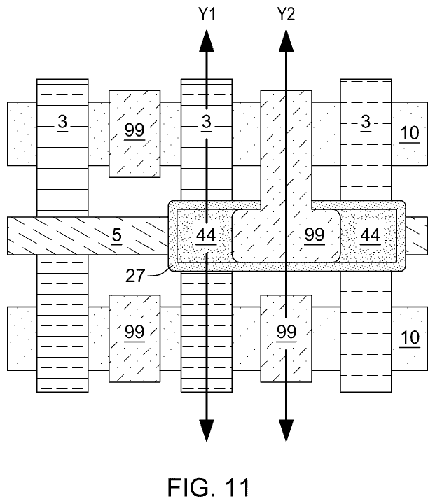

FIG. 11 depicts a top view of an illustration of a semiconductor design of the advanced semiconductor device with power rail cap 44 and source/drain contacts composed of contact metal 99, in accordance with an embodiment of the present invention. As depicted, FIG. 11 includes gate structures 3, active region 10, gate trench 5, liner 27 surrounding power rail cap 44, and contact material 99 for the S/D contacts and to connect to power rail 26. FIG. 11 also depicts the location of cross-sectional views Y1-Y1 of FIGS. 12A, 13A, and 14A and the location of cross-sectional views Y2-Y-2 of FIGS. 12B, 13B, and 14B. FIG. 11 depicts one illustration of a top view of the semiconductor design. In other examples, one or more gate structures 3, one or more S/D contact vias, one or more power rail caps 44, and one or more active region 10 may be present or may be in another location. In other examples, different device elements in different locations with power rail caps may be used (e.g., an array of memory devices).

FIG. 12A depicts a cross-sectional view Y1-Y1 of the semiconductor structure after a CMP removes the excess contact metal 99, in accordance with an embodiment of the present invention. As depicted, FIG. 12A includes the elements of FIG. 10A without contact metal 99 directly over ILD 33. Cross-sectional view Y1-Y1 through and parallel to one of gate 23 includes power rail cap 44 in ILD 13 above and contacting the top surface of recessed power rail 26. In FIG. 12A, power rail 26 with liner 27 is between two adjacent gate 23 and channels 12 in each of the GAA FETs. Power rail 26 extends from the top of ILD 13 through two of gate 23 and one of STI 20 to semiconductor material 4.

FIG. 12B depicts a cross-sectional view Y2-Y2 of the semiconductor structure after the CMP removes the excess power rail metal 99, in accordance with an embodiment of the present invention. As depicted, FIG. 12B includes the elements of FIG. 10B without contact metal 99 over ILD 33. Also, illustrated in FIG. 12B is the horizontal distance, X1, of the contact area contact metal 99 with power rail 26.

The contact area of contact metal 99 with power rail 26 is depicted with the horizontal distance labeled as width X1. The width X1, as depicted, is the horizontal width of power rail 26 in FIG. 12B. The width, X1, of the contact area of power rail 26 with contact metal 99 is the width of the S/D contact to the leftmost S/D 28 with power rail 26. The S/D contact for the leftmost S/D 28 in FIG. 12B contacts the top surface of power rail 26 and has a width that is equal to the width of power rail 26.

In some cases, when a top portion of the removed liner 27 exposes a portion of the sidewall of power rail 26. In these cases, the contact area between contact metal 99 and power rail 26 may include the exposed portion of the sidewall of power rail 26 and the width of the contact area of power rail 26 with contact metal 99 of the S/D contact is slightly greater than X1.

The semiconductor structure of FIG. 12B provides a larger contact area of contact metal 99 of the S/D contact with power rail 26 than a conventionally formed S/D contact or a conventionally formed S/D contact with misalignment to the power rail. The contact area of the leftmost S/D 28 with power rail 26 has a contact area width of X1 resulting in a wider horizontal contact width than a conventionally formed power rail (e.g., without power rail recessing and a power rail cap). The contact area width, X1, provides a lower electrical resistance between contact metal 99 of the S/D contact and power rail 26. Providing a larger contact area and a wider horizontal width, X1, of the contact area between contact metal 99 on the leftmost S/D contact and power rail 26 compared to conventionally formed power rails and S/D contacts can reduce the electrical resistance of the connection between the S/D contact and power rail 26. Providing a contact area between power rail 26 and the S/D contact with the width X1, increases the electrical performance of the semiconductor device when connected to the BSPDN compared to conventionally formed power rails with S/D contacts.

More specifically, in FIG. 12B, the horizontal width, X1, of the contact area of power rail 26 with contact metal 99 of the S/D contact to the leftmost S/D 28 is greater than the horizontal width of the contact area of a conventionally formed S/D contact with a conventional power rail.

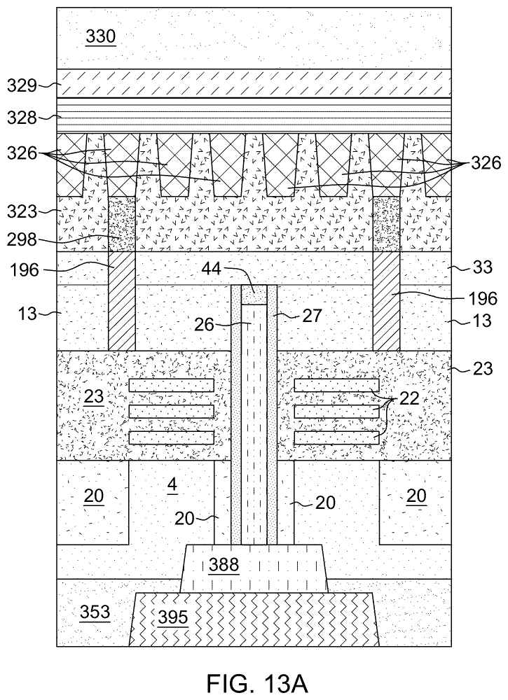

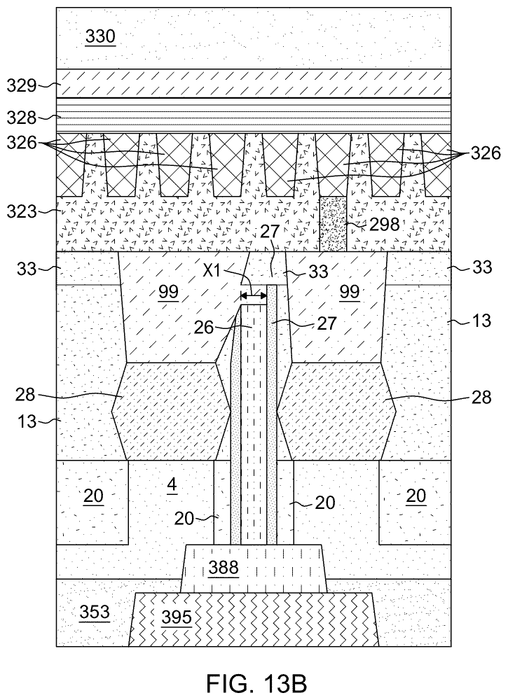

FIG. 13A depicts a cross-sectional view Y1-Y1 of the semiconductor structure after forming a backside power delivery network (BSPDN), in accordance with an embodiment of the present invention. As depicted, FIG. 13A includes the elements of FIG. 12A without substrate 2, etch stop layer 11, and portions of semiconductor material 4 and with backside ILD 353, backside via 388, and backside metal layer 395 added to form a portion of a BSPDN. FIG. 14A also includes gate contacts 196, ILD 323, via 298, metal layer 326, frontside interconnect wiring layers 328 formed using backend-of-line processes, bond layer 329, and carrier wafer 330 added to the elements of FIG. 12A.

FIG. 13A depicts the cross-sectional view Y1-Y1 of two GAA FETs separated by power rail 26 with power rail cap 44 used to provide the larger contact area between the leftmost S/D contact and power rail 26 depicted in FIG. 12B. While FIG. 13A depicts portions of two GAA FETs, as previously discussed, embodiments of the present invention are not limited to GAA FETs but can include embodiments with other logic devices (e.g., CMOS devices, planar or stacked FETs) and memory devices (e.g., stacked or arrays).

FIG. 13B depicts a cross-sectional view Y2-Y2 of the semiconductor structure after forming BSPDN, in accordance with an embodiment of the present invention. As depicted, FIG. 13B includes the elements of FIG. 13A without power rail cap 44. Also, included in FIG. 13B is width, X1, which is the width of the contact area of power rail 26 with contact metal 99 of the leftmost S/D 28, as previously discussed with respect to at least FIG. 10B and FIG. 12B.

FIG. 13B depicts the two GAA FETs with frontside interconnect wiring layers 328 and a BSPDN. Carrier wafer 330 bonds by bond layer 329 to frontside interconnect wiring layers 328. As previously discussed, using known semiconductor fabrication processes, frontside wiring interconnect layers 328 are formed where frontside wiring interconnect layers 328 connect to at least one of metal layer 326. Metal layer 326 connects by via 298 to the rightmost of S/D 28.

Also, depicted in FIG. 13B, using known semiconductor fabrication processes, power rail 26 connects by backside via 388 to metal layer 395 where metal layer 395 can be a metal layer of a BSPDN. As known to one skilled in the art, and as previously discussed, in other embodiments, one or more planar or stacked GAA FETs. In another embodiment, one or more of another type of logic device or one or more of a memory device (e.g., stacked memory devices) are formed using the processes or similar processes disclosed in embodiments of the present invention.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A semiconductor structure comprising:
a first portion of a source/drain (S/D) contact connecting to a first portion of a power rail adjacent to at least one semiconductor device, wherein the first portion of the S/D contact has a width equal to the width of a top surface of the power rail; and
a power rail cap on a second portion of a power rail.

2. The semiconductor structure of claim 1, wherein the first portion of the S/D contact is above a top surface of a source/drain of the semiconductor device, and wherein a second portion of the S/D contact connects to the top surface of the source/drain.

3. The semiconductor structure of claim 1, wherein the power rail includes a liner surrounding a sidewall of the power rail.

4. The semiconductor structure of claim 2, wherein the power rail has a top surface above the top surface of the source/drain, and wherein the power rail extends down to a bottom surface of an isolation trench in a portion of a semiconductor substrate.

5. The semiconductor structure of claim 1, wherein the first portion of the S/D contact connecting to the first portion of the power rail has a height that is at least equal to a thickness of the power rail cap.

6. The semiconductor structure of claim 1, wherein the power rail connects by one or more backside vias to a backside power delivery network.

7. The semiconductor structure of claim 1, wherein the semiconductor device is selected from a group consisting of a logic device, a memory device, one or more stacked logic devices, and one or more stacked memory devices.

8. A semiconductor structure comprising:
a power rail between two gate-all-around field-effect transistors (GAA FETs);
a first portion of a source/drain (S/D) contact connecting to a first portion of the power rail, wherein a width of the first portion of the S/D contact is equal to the width of the power rail; and
a power rail cap contacting a top surface of a second portion of the power rail.

9. The semiconductor structure of claim 8, wherein the power rail has a sidewall electrically isolated from a gate of each of the two GAA FETs by a liner.

10. The semiconductor structure of claim 9, wherein the power rail cap contacting the second portion of the power rail is between and above the gate of each of the two GAA FETs.

11. The semiconductor structure claim 9, wherein the first portion of the S/D contact connecting to the first portion of the power rail is above each source/drain of the two GAA FETs.

12. The semiconductor structure of claim 11, wherein a second portion of the S/D contact contacts at least one of the source/drains.

13. The semiconductor structure of claim 8, wherein a height of the first portion of the S/D contact connecting to the second portion of the power rail is equal to the height of the power rail cap.

14. The semiconductor structure of claim 9, wherein a top surface of the S/D contact is below the top surface of the power rail cap.

15. The semiconductor structure of claim 8, wherein a bottom surface of the power rail is level with a bottom surface of an isolation trench in a semiconductor substrate, and wherein the top surface of the power rail is above a top surface of a source/drain of each of the two GAA FETs.

16. The semiconductor structure of claim 8, further comprising:
a carrier wafer contacting one or more layers of frontside interconnect wiring;
one or more levels of metal layers connecting to the one or more layers of frontside interconnect wiring;
one or more vias connecting the one or more levels of metal layers to one or more contacts to at least one source/drain and each gate of each of the two GAA FETs;
a backside via connecting the power rail to a first metal layer of a backside power delivery network, wherein the power rail is a buried power rail.

17. A method of forming a power rail with a power rail cap between two semiconductor devices comprising:
forming two semiconductor devices on a semiconductor material, wherein the two semiconductor devices are separated by a power rail with a liner;
recessing the power rail;
depositing a power rail cap material over the recessed power rail and a first dielectric material on each of the two semiconductor devices;
performing a chemical-mechanical polish to remove the power rail cap above the first dielectric material;
creating an opening over each source/drain of the two semiconductor devices by removing portions of the first dielectric material and a second dielectric material, wherein the second dielectric material is deposited on the first dielectric material;
removing a portion of the power rail cap above a first portion of the power rail, wherein the portion of the power rail cap removed contacts the opening over one of a source/drain of one of the two semiconductor devices;
depositing a contact metal, wherein the contact metal deposits on the second dielectric material, on each of the source/drains, and the first portion of the power rail;
removing the contact metal above the second dielectric material, wherein a first portion of the contact metal resides on a top surface of the power rail and a second portion of the contact metal resides on each of the source/drains.

18. The method of claim 17, wherein the first portion of the contact metal residing on the top surface of the power rail has contact area width with the power rail that is equal to a width of the top surface of the power rail.

19. The method of claim 17, further comprising:
forming the power rail contacting a backside via and a backside interlayer dielectric; and
forming one or more or backside interconnect layers contacting by the backside via to the power rail, wherein the power rail is a buried power rail.

20. The method of claim 17, wherein the first portion of the contact metal residing on the top surface of the first portion of the power rail has a width equal to the width of the top surface of the power rail.
